(19) United States
(12) Patent Application Publication
(10) Pub. No.: US 2024/0191335 A1
(43) Pub. Date: Jun. 13, 2024

(54) METAL MASK AND METHOD TO PRODUCE METAL MASK

(71) Applicant: DARWIN PRECISIONS CORPORATION, Hsinchu County (TW)

(72) Inventors: KANG-HSIANG LIU, Hsinchu County (TW); Chi-Wei Lin, Hsinchu County (TW)

(21) Appl. No.: 18/132,439

(22) Filed: Apr. 10, 2023

(30) Foreign Application Priority Data
Dec. 9, 2022 (TW) 111147434

(51) Int. Cl. C23C 14/04; C23C 14/24

(52) U.S. Cl. CPC C23C 14/042; C23C 14/24

(57) ABSTRACT

A metal mask includes a metal panel, provided with an evaporation surface and a back surface opposite to each other and a plurality of through holes extending from the evaporation surface to the back surface. A size of each through hole decreases gradually from the evaporation surface towards the back surface. A first opening is formed by each through hole in the evaporation surface. The first opening includes a primary opening part and a plurality of secondary opening parts. The primary opening part is provided with two long edges opposite to each other and two short edges opposite to each other. The two short edges are connected between the two long edges, and the secondary opening parts are connected at two ends of the long edges. Each secondary opening part has a width perpendicular to the length. A method to produce the metal mask is also provided.

### FIELD OF THE INVENTION

The present invention relates to a metal mask and a method to produce the metal mask, and more particularly to a metal mask and a method to produce the metal mask applied to making a screen plate.

### BACKGROUND OF THE INVENTION

An Organic Light-Emitting Diode (OLED) panel produced by applying an OLED technique, featuring self-illumination, wide visual angle, power saving, high efficiency, response time, lightness and thinness and the like becomes a primary component of a display panel of a mobile phone in the current market.

In a structure of the OLED panel, a glass substrate and an organic light-emitting material layer on the glass substrate are included. The organic light-emitting material layer primarily includes a plurality of light-emitting patterns which are produced primarily by evaporating Fine Metal Mask (FMM) in a matched manner on the glass substrate. Through holes in the FMM decide either the collocating positions of the light-emitting patterns on the glass substrate or the sizes, fineness of the light-emitting patterns, which further affects the display quality of the OLED panel.

### SUMMARY OF THE INVENTION

The present invention provides a metal mask with a good through hole shape and less influence of the shadow effect during evaporation.

The present invention further provides a method to produce the metal mask. The produced metal mask has a good through hole shape and less influence of the shadow effect during evaporation.

To achieve the above advantages, an embodiment of the present invention provides a metal mask, including a metal panel. The metal panel is provided with an evaporation surface and a back surface opposite to each other and a plurality of through holes extending from the evaporation surface to the back surface, wherein a size of each through hole decreases gradually from the evaporation surface towards the back surface, a first opening is formed by each through hole in the evaporation surface, the first opening includes a primary opening part and a plurality of secondary opening parts, the primary opening part is provided with two long edges opposite to each other and two short edges opposite to each other, the two short edges are connected between the two long edges, and the secondary opening parts are connected at two ends of the long edges; each secondary opening part has a length parallel to the long edges, and the length is greater than 15 μm but less than 45 μm, and each secondary opening part has a width perpendicular to the length, and the width is greater than 0 μm but less than 10 μm.

In an embodiment of the present invention, a second opening is formed by each through hole in the back surface and an etched opening is formed between the evaporation surface and the back surface, the second opening is provided with first corresponding edges corresponding to the short edges, respectively, the etched opening is provided with second corresponding edges corresponding to the short edges, and in a direction parallel to the two long edges, a distance between each of first corresponding edges and a corresponding one of the second corresponding edges is less than 5 μm.

In an embodiment of the present invention, a thickness of the metal panel is between 15 μm and 50 μm.

In an embodiment of the present invention, a length ratio of each of the two long edges to each of the two short edges is between 2 and 6.

The present invention further provides a method to produce a metal mask, including the following steps: providing a metal panel, wherein the metal panel is provided with an evaporation surface and a back surface opposite to each other; forming a first patterned photoresist layer on the evaporation surface and forming a second patterned photoresist layer on the back surface, wherein the first patterned photoresist layer includes a plurality of first photoresist openings, the second patterned photoresist layer includes a plurality of second photoresist openings, the second photoresist openings correspond to the first photoresist openings in position, respectively, and the sizes of the second photoresist openings are smaller than those of the first photoresist openings, wherein each of the first photoresist openings comprises a primary photoresist opening part and a plurality of secondary photoresist opening parts, the primary photoresist opening part is provided with two long edges opposite to each other and two short edge opposite to each other, the two short edges are connected between the two long edges, and the secondary photoresist opening parts are connected to both ends of each of the two long edges; and etching the metal panel to form a plurality of through holes, wherein a size of each through hole decreases gradually from the evaporation surface towards the back surface, a first opening is formed by each through hole in the evaporation surface, the first opening includes a primary opening part and a plurality of secondary opening parts, the primary opening part is provided with two long edges opposite to each other and two short edges opposite to each other, the two short edges are connected between the two long edges, and the secondary opening parts are connected at two ends of the long edges; each secondary opening part has a length parallel to the long edges, and the length is greater than 15 μm but less than 45 μm, and each secondary opening part has a width perpendicular to the length, and the width is greater than 0 μm but less than 10 μm.

In an embodiment of the present invention, each secondary photoresist opening part includes a trapezoidal opening, the trapezoidal opening is provided with a bottom edge, a top edge, a first waist edge and a second waist edge, the bottom edge is connected to the primary photoresist opening part, the first waist edge is parallel to and connected to one of the two short edges of the primary photoresist opening part, and the second waist edge inclines to the two long edges.

In an embodiment of the present invention, a distance between the bottom edge and the top edge is less than 10 μm.

In an embodiment of the present invention, the top edge has a first length in a direction parallel to the two long edges, and the first length is greater than 5 μm but less than 15 μm; and the bottom edge has a second length in a direction parallel to the two long edges, and the second length is greater than 10 μm but less than 30 μm.

According to the above description, in the metal mask provided by the present invention, the first opening formed by the through hole in the evaporation surface is designed in shape. By dividing the first opening into the primary opening and the plurality of secondary openings located in the long edges of the primary opening and adjusting the sizes of the secondary openings, the produced metal mask may have the etched opening with a good shape, and meanwhile, the influence of the shadow effect can be reduced because the distance between the edge of the second opening in the back surface and the edge of the etched opening is less than a certain size. Moreover, the present invention further provides a method to produce the metal mask.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic diagram of a metal mask in an embodiment of the present invention;

FIG. 2 is a sectional schematic diagram of a through hole in the embodiment of FIG. 1;

FIG. 3 is a schematic diagram of a first opening, a first photoresist opening and the through hole view from an evaporation surface in the embodiment of FIG. 1;

FIG. 4 is an enlarged schematic diagram of a secondary opening in the embodiment of FIG. 1;

FIG. 5A and FIG. 5B are flow diagrams of a method to produce the metal mask in an embodiment of the present invention;

FIG. 6 is an enlarged schematic diagram of a secondary photoresist opening part in the embodiment of FIG. 1;

FIG. 7 is a comparison diagram of the through holes in different embodiments of the present invention with fixed extended length and changed extended range; and

FIG. 8 is a comparison diagram of the through holes in different embodiments of the present invention with fixed extended range and changed extended length.

### DETAILED DESCRIPTION OF PREFERRED EMBODIMENTS

Terms used in the description of the embodiments of the present invention, for example, orientation or position relation such as “above” and “below” are described according to the orientation or position relation shown in the drawings. The above terms are used for facilitating description of the present invention rather than limiting the present invention, i.e., indicating or implying that the mentioned elements have to have specific orientations and to be configured in the specific orientations. In addition, terms such as “first” and “second” involved in the description or claims are merely used for naming the elements or distinguishing different embodiments or ranges rather than limiting the upper limit or lower limit of the quantity of the elements.

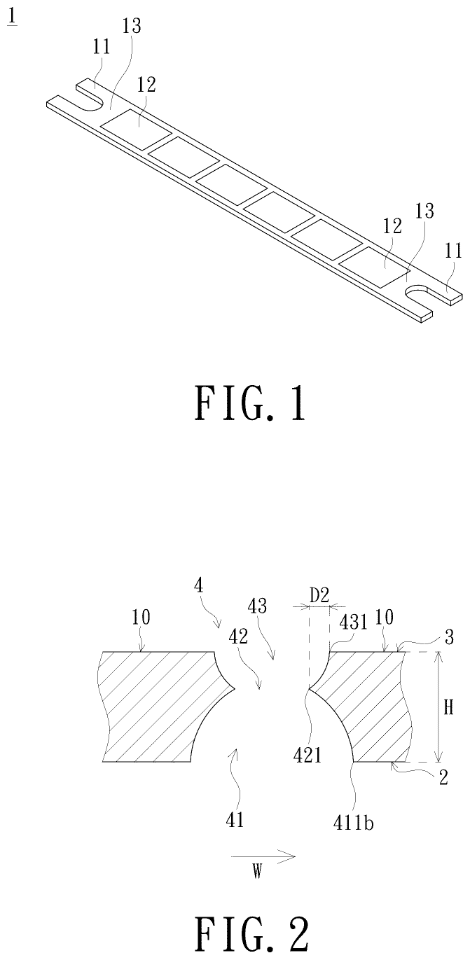

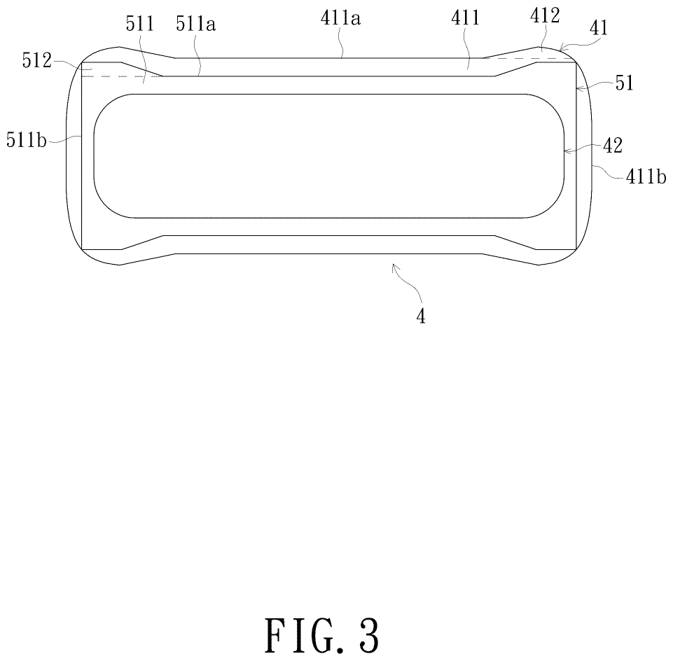

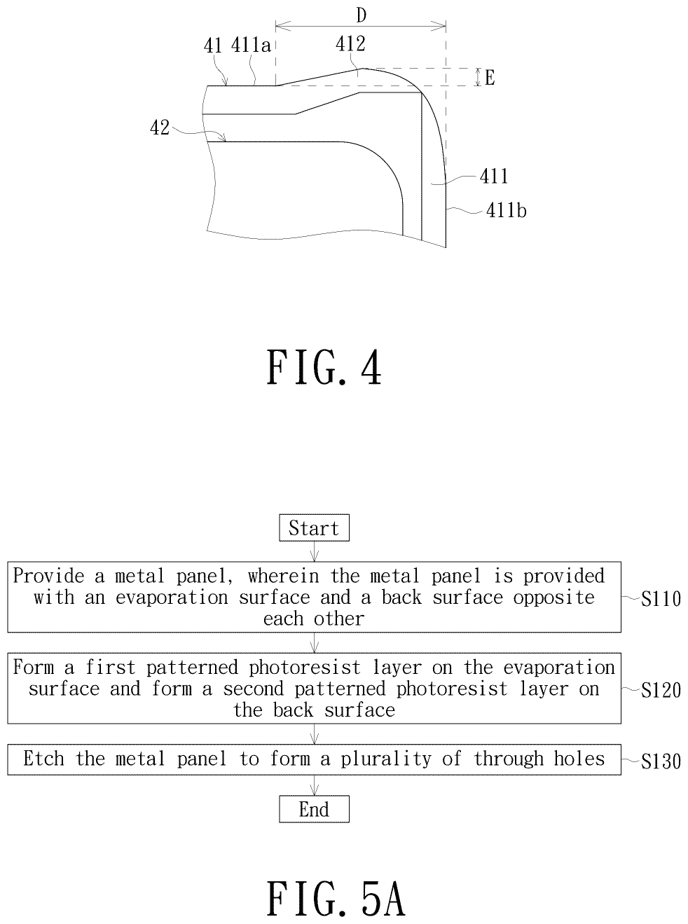

FIG. 1 is a schematic diagram of a metal mask in an embodiment of the present invention. FIG. 2 is a sectional schematic diagram of a through hole in the embodiment of FIG. 1. FIG. 3 is a schematic diagram of a first opening, a first photoresist opening and the through hole view from an evaporation surface in the embodiment of FIG. 1. FIG. 4 is an enlarged schematic diagram of a secondary opening in the embodiment of FIG. 1.

As shown in FIG. 1, a metal mask 1 provided by the present invention includes a metal panel 10. The metal panel 10 includes an evaporation surface 2 and a back surface 3 opposite to each other and a plurality of through holes 4 extending from the evaporation surface 2 towards the back surface 3. As shown in FIG. 2 and FIG. 3, for example, a size of each through hole 4 decreases gradually from the evaporation surface 2 towards the back surface 3, and a first opening 41 is formed by each through hole 4 in the evaporation surface 2. The first opening 41 includes a primary opening part 411 and a plurality of secondary opening parts 412, wherein the primary opening part 411 is provided with two long edges 411a opposite to each other and two short edges 411b opposite to each other. The two short edges 411b are connected between the two long edges 411a, and the secondary opening parts 412 are connected at two ends of each long edge 411a. As shown in FIG. 4, each secondary opening part 412 has a length D parallel to the long edges 411a, and each secondary opening part 412 has a width E perpendicular to the long edges 411a. In different embodiments of the present invention, the length D is, for example, greater than 15 μm but less than 45 μm, and the width E is, for example, greater than 0 μm but less than 10 μm.

As shown in FIG. 1 and FIG. 2, the metal panel 10 is, for example, strip-like, clamping parts 11 are arranged at two opposite to ends of the metal mask 1, and the clamping parts 11 are suitable for being connected to a clamp (not shown in the drawings) during use of the metal mask 1. A through hole part 12 is further arranged between the two clamping parts 11, and each through hole 4 is located in the through hole part 12. Furthermore, for example, welding parts 13 are respectively arranged between the clamping parts 11 and the through hole part 12, and the welding parts 13 are suitable for being welded to a frame (not shown in the drawings) during use of the metal mask 1. In the through hole part 12, the thickness H of the metal panel 10 is, for example, between 15 μm and 50 μm, and the metal panel is made from, for example, a nickel iron alloy.

As shown in FIG. 2 and FIG. 3, a second opening 43 is formed by each through hole 4 of the metal mask 1 in the back surface 3, an etched opening 42 is formed between the back surface 3 and the evaporation surface 2, and the second opening 43 and the etched opening 42 substantially correspond to the primary opening part 411 in shape. In an embodiment of the present invention, a length ratio of each of the two long edges 411a to each of the two short edges 411b of the primary opening part 411 is, for example, between 2 and 6.

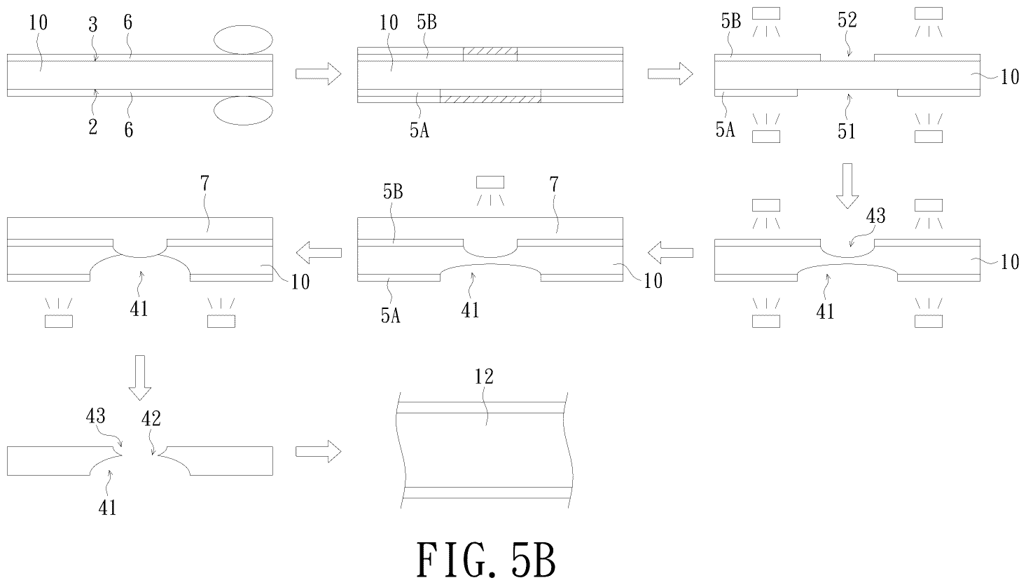

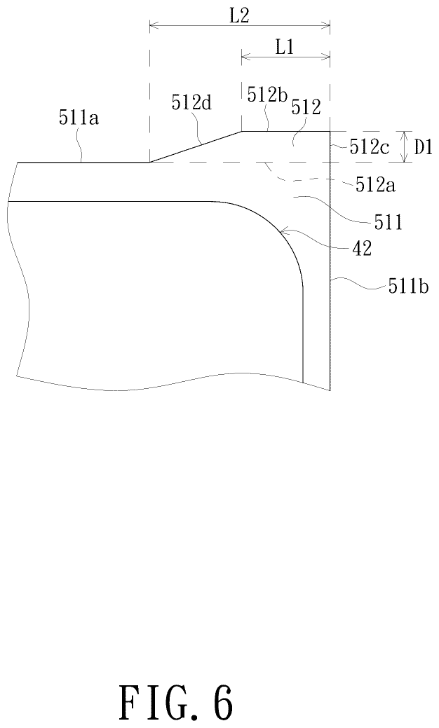

FIG. 5A and FIG. 5B are flow diagrams of a method to produce the metal mask 1 in an embodiment of the present invention. FIG. 6 is an enlarged schematic diagram of a secondary photoresist opening part in the embodiment of FIG. 1. To produce the metal mask 1 with the above size, with reference to FIG. 4 and FIG. 6, the present invention provides a method to produce a metal mask 1, including the following steps: S110: providing a metal panel 10, wherein the metal panel 10 is provided with an evaporation surface 2 and a back surface 3 opposite to each other; S120: forming a first patterned photoresist layer 5A on the evaporation surface 2 and forming a second patterned photoresist layer 5B on the back surface 3; and S130: etching the metal panel 10 to form a plurality of through holes 4. In S120, the first patterned photoresist layer 5A includes a plurality of first photoresist openings 51, the second patterned photoresist layer 5B includes a plurality of second photoresist openings 52, the second photoresist openings 52 correspond to the first photoresist openings 51 in position, respectively, and the sizes of the second photoresist openings 52 are smaller than those of the first photoresist openings 51.

As shown in FIG. 5B, in S120, the way to form the first patterned photoresist layer 5A and the second patterned photoresist layer 5B includes, for example, coating the evaporation surface 2 and the back surface 3 of the metal panel 10 with a photoresist coating 6 for exposure and development so as to form the first patterned photoresist layer 5A on the evaporation surface 2 of the metal panel 10 and forming the second patterned photoresist layer 5B on the back surface 3. The photoresist coating 6 is, for example, a negative photoresist, but is not limited thereto. In addition, S130, for example, includes: etching the metal panel 10 twice, and then removing the first patterned photoresist layer 5A and the second patterned photoresist layer 5B and a protective layer 7 additionally applied in the process so as to form the through hole 4 and the through hole part 12 on the metal panel 10.

It can be known from FIG. 5B that after first time etching, the first opening 41 is formed on the evaporation surface 2 of the metal panel 10, and the second opening 43 is formed on the back surface 3. Next, when second time etching is performed, the protective layer 7 is formed on the back surface 3 first, then etching is performed from the evaporation surface 2 to form the through hole 4 passing through the metal panel 10, and etching is performed via the first opening 41 to the protective layer 7 to form the etched opening 42. From the perspective of etching quantity, it can be seen from FIG. 5B that in the extension direction of the through hole 4, the distance from the first opening 41 to the etched opening 42 is greater than that from the second opening 43 to the etched opening 42.

In the process to produce the metal mask 1, when the second time etching is performed, as a result of large differences in lengths of the long edges and the short edges of the through hole 4, different etching quantities will be generated in different directions in the etching process, which induces different influence to the shapes of the first opening 41, the etched opening 42 and the second opening 43 of the metal mask 1. Due to duration of the etching time, it may result in the following two circumstances: when the etching time is longer, the long edges of the etched opening 42 deform, so the light-emitting patterns produced by evaporating the metal mask 1 on the glass substrate (not shown in the drawings) will deform. When the etching time is shorter, although the etched opening 42 with good shape can be formed, the light-emitting patterns generated by evaporation are severely affected by the shadow effect because the short edges 431 (shown in FIG. 2) of the second opening 43 will generate a large notch on the back surface 3. To cope with the above circumstances, reference on the following structure description will be made below.

As shown in FIG. 4 and FIG. 5B, the size of each first photoresist opening 51 is smaller than that of the first opening 41, and the first photoresist opening substantially corresponds to the first opening 41 in shape. In other words, as the first opening 41 is provided with the primary opening part 411 and secondary opening parts 412, each first photoresist opening 51 includes the corresponding primary photoresist opening parts 511 and a plurality of secondary photoresist opening parts 512, the primary photoresist opening part 511 is provided with two long edges 511a opposite to each other and two short edges 511b opposite to each other, the two short edges 511b are connected between the two long edges 511a, and the secondary photoresist opening parts 512 are connected to both ends of each long edge 511a.

As shown in FIG. 6, in the embodiment of the present invention, each secondary photoresist opening part 512 includes a trapezoidal opening, the trapezoidal opening is provided with a bottom edge 512a, a top edge 512b, a first waist edge 512c and a second waist edge 512d, the bottom edge 512a is connected to the primary photoresist opening part 511, the first waist edge 512c is parallel to and connected to one of the two short edges 511b of the primary photoresist opening part 511, and the second waist edge 512d inclines to the two long edges 511a.

To produce the first opening 41 with the size of the secondary opening part 412, as shown in FIG. 3 and FIG. 6, in the embodiment of the present invention, the distance D1 between the bottom edge 512a and the top edge 512b of the secondary photoresist opening part 512 is, for example, less than 10 μm, the top edge 512b has a first length L1 in the direction parallel to the long edges 511a, and the first length L1 is, for example, greater than 5 μm but less than 15 μm; and the bottom edge 512a has a second length L2 in the direction parallel to the long edges 511a, and the second length L2 is, for example, greater than 10 μm but less than 30 μm. It can be known from FIG. 6 that in the embodiment, the extension direction of the edge of the short edge 511b of the primary photoresist opening part 511 and that of the first waist edge 512c of the secondary photoresist opening part 512 are, for example, located on a same straight line.

Referring to FIG. 2, FIG. 3 and FIG. 5B, thus, according to the metal mask 1 produced by the method, the contour shape of the first opening 41 can be substantially equal to that of the first photoresist opening 51, and during the second time etching, etching in a lateral side (the direction nonperpendicular to the opening direction of the through hole 4) will be generated in the first opening 41. Therefore, the contour size of the first opening 41 will be greater than that of the first photoresist opening 51 (as shown in FIG. 3). Viewed from the back surface 3, the second opening 43 has the first corresponding edges 431 corresponding to the short edges 411b, the etched opening 42 has the second corresponding edges 421 corresponding to the short edges 411b, and in the direction W parallel to the long edges 411a, the distance D2 between each first corresponding edge 431 and one of the second corresponding edges 421 can be less than 5 μm. Thus, in the secondary opening parts 412, as the distance D2 between each first corresponding edge 431 and one of the second corresponding edges 421 is less than 5 μm, the influence of the shadow effect can be reduced during use. Similarly, when the metal mask 1 produced by the method is evaporated, in the presence of the secondary opening parts 412, an evaporation material can be smoothly evaporated in a position of a corner of the glass substrate (not shown in the drawings) corresponding to the etched opening 42, so that a pattern corresponding to the etched opening 42 can be smoothly formed.

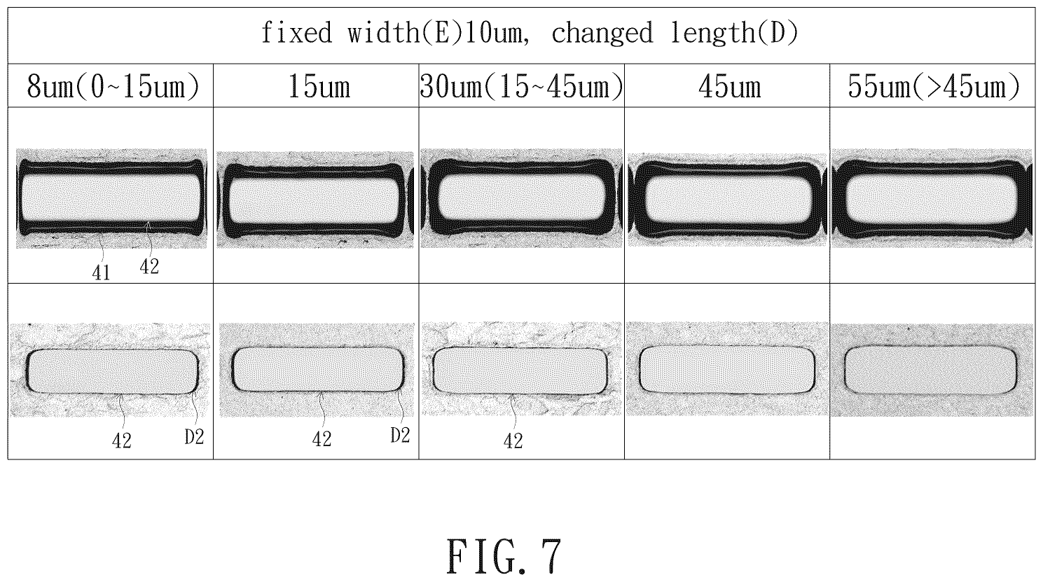

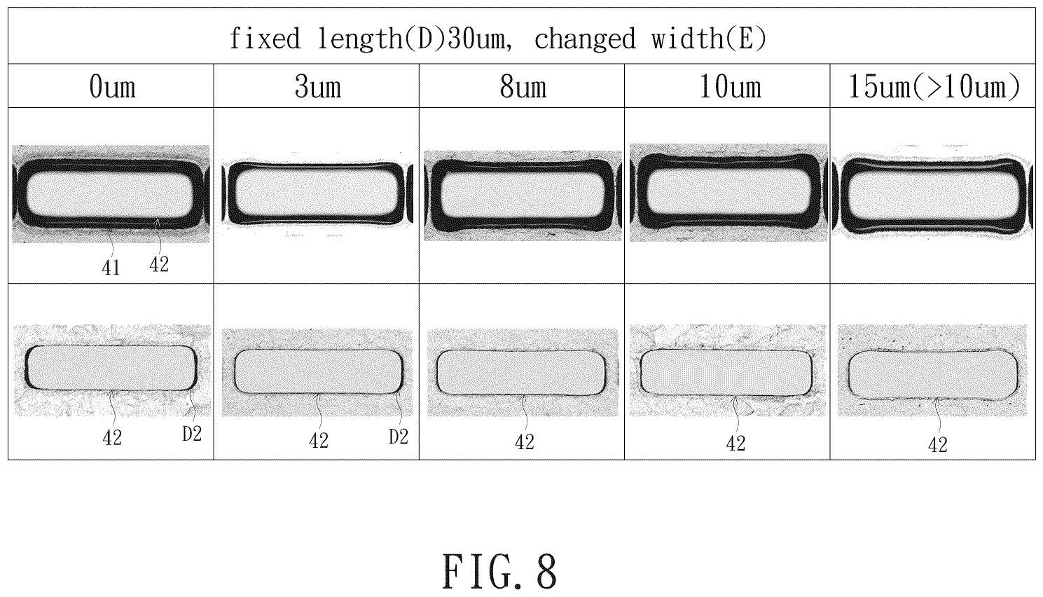

FIG. 7 is a comparison diagram of the through holes in different embodiments of the present invention with fixed width and changed length. FIG. 8 is a comparison diagram of the through holes in different embodiments of the present invention with fixed length and changed width. As described in the above paragraphs, when the metal mask 1 is produced by an etching method, in a case where the length-width ratio of the second opening 43 is great (for example, 2-6), in order to produce the through hole 4 where the distance D2 between the first corresponding edge 431 and the second corresponding edge 421 is less than 5 μm, the size of the secondary opening part 412 needs to be adjusted with reference to the following actual experimental diagram. FIG. 7 is a diagram of the actual through hole 4 with fixed width E (for example, 10 μm) of the secondary opening part 412 and various changed lengths D.

Referring to FIG. 2, FIG. 3 and FIG. 7, FIG. 7 shows graph groups of embodiments with the length D being 8 μm (between 0 μm and 15 μm), 15 μm, 30 μm (between 15 μm and 45 μm), 45 μm and 55 μm at the same processing time from left to right, wherein each graph group can be divided into two columns, which are respectively a graph (above column) representing a contour between the first opening 41 and the etched opening 42 observed from the side where the evaporation surface 2 of the metal mask 1 is located, and the graph group in the lower column is a graph representing the etched opening 42 and the second opening 43 observed from the side where the back surface 3 of the metal mask 1 is located. As the contours of the etched opening 42 and the second opening 43 are quite similar, the symbol of the etched opening 42 is only marked, and when the distance D2 between the etched opening 42 and the second opening 43 is great, the distance D2 is marked.

It can be known from FIG. 7 that when the width E is 10 μm and the length D is less than 15 μm, although the etched opening 42 is rectangular, the distance D2 between the first corresponding edge 431 of the second opening 43 and the second corresponding edge 421 (shown in FIG. 2) of the etched opening 42 is greater than 5 μm. When the length D is adjusted to 15 μm under a condition of same width E, although the etched opening 42 is rectangular as well and the distance D2 between the first corresponding edge 431 and the second corresponding edge 421 of the etched opening 42 is gradually reduced, the distance D2 between the first corresponding edge 431 and the second corresponding edge 421 is substantially within a range of 4.5-5.5 μm. Therefore, the value of the length D is in a range greater than 15 μm during production. As shown in FIG. 7, when the width E is 10 μm and the length D is 30 μm (between 15 μm and 45 μm), the etched opening 42 is rectangular as well and the distance D2 between the first corresponding edge 431 and the second corresponding edge 421 is less than 5 μm, so that the influence of the shadow effect can be reduced. When the length D gradually increases to 45 μm, although the distance D2 between the first corresponding edge 431 and the second corresponding edge 421 is still less than 5 μm, it can be observed that the long edges of the etched opening 42 are twisted. Therefore, the maximum value of the length D is less than 45 μm. Finally, when the width E is 10 μm and the length D is 55 μm (greater than 45 μm), it can be observed that the distance D2 between the first corresponding edge 431 and the second corresponding edge 421 is less than 5 μm, but the long edges of the etched opening 42 have been twisted.

Referring to FIG. 2, FIG. 3 and FIG. 8, FIG. 8 shows graph groups of embodiments with the width E being 0 μm, 3 μm (between 0 μm and 10 μm), 8 μm (between 0 μm and 10 μm), 10 μm (between 0 μm and 10 μm) and 15 μm (greater than 10 μm) at the same processing time from left to right. As shown in FIG. 8, when the length D is 30 μm and the width E is 0 μm, although the etched opening 42 is rectangular, the distance D2 between the first corresponding edge 431 of the second opening 43 and the second corresponding edge 421 (shown in FIG. 2) of the etched opening 42 is greater than 5 μm, a thicker black edge can be observed. When the width E is adjusted to 3 μm under the condition of same length D, although the etched opening 42 is still rectangular, the distance D2 between the first corresponding edge 431 and the second corresponding edge 421 of the etched opening 42 has decreased to be less than 5 μm, so the influence of the shadow effect can be reduced. Therefore, the value of the width E is in a range of greater than 0 μm during production. As shown in the drawings, when the length D is kept at 30 μm and the width E is 8 μm (between 0 μm and 10 μm), the etched opening 42 is still rectangular, and the distance D2 between the first corresponding edge 431 and the second corresponding edge 421 is still less than 5 μm. When the width E gradually increases to 10 μm, although the distance D1 between the first corresponding edge 431 and the second corresponding edge 421 is still less than 5 μm, it can be observed that the long edges of the etched opening 42 are twisted. Therefore, the maximum value of the width E is less than 10 μm. As shown in FIG. 8, when the width E is kept at 30 μm and the length D is 15 μm (greater than 10 μm), it can be observed that the distance D2 between the first corresponding edge 431 and the second corresponding edge 421 is less than 5 μm, but the long edges of the etched opening 42 have been twisted.

It can be known from FIG. 7, FIG. 8 as well as FIG. 2 and FIG. 3 that even though the through hole 4 of the metal mask 1 is provided with the primary opening part 411 and the secondary opening parts 412, it still needs to adjust the sizes of the secondary opening parts 412 to generate the through hole 4 with better integral shape, so as to form the light-emitting pattern with the good shape on the glass substrate.

By designing the through hole with the above shape and size, dividing the first opening into the primary opening and the plurality of secondary openings located in the long edges of the primary opening and adjusting the sizes of the secondary openings, the produced metal mask may have the evaporated opening with the good shape, and meanwhile, the influence of the shadow effect can be reduced because the distance between the edge of the second opening and the edge of the evaporated opening is less than a certain size.

According to the above description, in the metal mask provided by the present invention, the first opening formed by the through hole in the evaporation surface is designed in shape. By dividing the first opening into the primary opening and the plurality of secondary openings located in the long edges of the primary opening and adjusting the sizes of the secondary openings, the produced metal mask may have the etched opening with a good shape, and meanwhile, the influence of the shadow effect can be reduced because the distance between the edge of the second opening in the back surface and the edge of the etched opening is less than a certain size. Moreover, the present invention further provides a method to produce the metal mask.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A metal mask, comprising:
a metal panel, provided with an evaporation surface and a back surface opposite to each other and a plurality of through holes extending from the evaporation surface to the back surface, wherein a size of each of the through holes decreases gradually from the evaporation surface towards the back surface, a first opening is formed by each of the through holes in the evaporation surface, the first opening comprises a primary opening part and a plurality of secondary opening parts, the primary opening part is provided with two long edges opposite to each other and two short edges opposite to each other, the two short edges are connected between the two long edges, and the secondary opening parts are connected at two ends of the long edges; and wherein each of the secondary opening parts has a length parallel to the long edges, and the length is greater than 15 μm but less than 45 μm, and each of the secondary opening parts has a width perpendicular to the length, and the width is greater than 0 μm but less than 10 μm.

2. The metal mask according to claim 1, wherein a second opening is formed by each of the through holes in the back surface and an etched opening is formed between the evaporation surface and the back surface, the second opening is provided with two first corresponding edges corresponding to the two short edges, respectively, the etched opening is provided with second corresponding edges corresponding to the two short edges, and in a direction parallel to the two long edges, a distance between each of first corresponding edges and a corresponding one of the second corresponding edges is less than 5 μm.

3. The metal mask according to claim 1, wherein a thickness of the metal panel is between 15 μm and 50 μm.

4. The metal mask according to claim 1, wherein a length ratio of each of the two long edges to each of the two short edges is between 2 and 6.

5. A method to produce a metal mask, the method comprising:
providing a metal panel, wherein the metal panel is provided with an evaporation surface and a back surface opposite to each other;
forming a first patterned photoresist layer on the evaporation surface and forming a second patterned photoresist layer on the back surface, wherein the first patterned photoresist layer comprises a plurality of first photoresist openings, the second patterned photoresist layer comprises a plurality of second photoresist openings, the second photoresist openings correspond to the first photoresist openings in position, respectively, and the sizes of the second photoresist openings are smaller than those of the first photoresist openings, wherein each of the first photoresist openings comprises a primary photoresist opening part and a plurality of secondary photoresist opening parts, the primary photoresist opening part is provided with two long edges opposite to each other and two short edge opposite to each other, the two short edges are connected between the two long edges, and the secondary photoresist opening parts are connected to both ends of each of the two long edges; and
etching the metal panel to form a plurality of through holes, wherein a size of each of the through holes decreases gradually from the evaporation surface towards the back surface, a first opening is formed by each of the through holes in the evaporation surface, the first opening comprises a primary opening part and a plurality of secondary opening parts, the primary opening part is provided with two long edges opposite to each other and two short edges opposite to each other, the two short edges are connected between the two long edges, and the secondary opening parts are connected at two ends of the long edges; each of the secondary opening parts has a length parallel to the long edges, and the length is greater than 15 μm but less than 45 μm, and each of the secondary opening parts has a width perpendicular to the length, and the width is greater than 0 μm but less than 10 μm.

6. The method to produce a metal mask according to claim 5, wherein each of the secondary photoresist opening parts comprises a trapezoidal opening, the trapezoidal opening is provided with a bottom edge, a top edge, a first waist edge and a second waist edge, the bottom edge is connected to the primary photoresist opening part, the first waist edge is parallel to and connected to one of the two short edges of the primary photoresist opening part, and the second waist edge inclines to the two long edges.

7. The method to produce a metal mask according to claim 6, wherein a distance between the bottom edge and the top edge is less than 10 μm.

8. The method to produce a metal mask according to claim 6, wherein the top edge has a first length in a direction parallel to the two long edges, and the first length is greater than 5 μm but less than 15 μm; and the bottom edge has a second length in a direction parallel to the two long edges, and the second length is greater than 10 μm but less than 30 μm.
